(19) United States
(12) Patent Application Publication
(10) Pub. No.: US 2020/0127216 A1
(43) Pub. Date: Apr. 23, 2020

(54) OLED DISPLAY APPARATUS

(71) Applicant: Wuhan China Star Optoelectronics Semiconductor Display Technology Co., Ltd., Wuhan,Hubei (CN)

(72) Inventor: Qingliang TAO, Wuhan, Hubei (CN)

(73) Assignee: Wuhan China Star Optoelectronics Semiconductor Display Technology Co., Ltd, Wuhan, Hubei (CN)

(21) Appl. No.: 16/317,581

(22) PCT Filed: Aug. 27, 2018
(86) PCT No.: PCT/CN2018/102466

§ 371 Date: Jan. 14, 2019

(30) Foreign Application Priority Data
Aug. 3, 2018 (CN) 201810874838.1

(51) Int. Cl. H01L 51/00; H01L 27/32; H01L 51/52

(52) U.S. Cl. CPC H01L 51/0097; H01L 27/3262; H01L 51/5253; H01L 29/42384; H01L 2251/5338; H01L 2251/558; H01L 2251/301

(57) ABSTRACT

The present disclosure provides an organic light emitting diode (OLED) display apparatus. The OLED display apparatus includes a flexible substrate, a TFT layer, an OLED illumination layer, and a thin film encapsulation layer. The TFT layer includes at least two trenches at a location corresponding to the non-display area. The thin film encapsulation layer includes a first inorganic layer, an organic layer, and a second inorganic layer that are stacked from bottom to top, and the first inorganic layer and the second inorganic layer cover the trenches.

### FIELD OF INVENTION

The present disclosure relates to the field of display technology, and more particularly to an organic light emitting diode (OLED) display apparatus.

### BACKGROUND

Having advantages of self-illumination, outstanding color reproduction, and flexible property, OLED display apparatuses are considered as a substitute to replace conventional liquid crystal displays (LCDs). However, OLED devices are extremely sensitive to water and oxygen, where water and oxygen may enter OLED devices, influencing lifetime of OLED devices. Therefore, OLED devices are required to be encapsulated. Currently, thin film encapsulation is a technique used to encapsulate OLED devices.

Thin film encapsulation involves establishing a sandwich structure, where two inorganic layers are formed for blocking water and oxygen, and one organic layer sandwiched between the two inorganic layers is to facilitate planarization and act as a buffer. If the two inorganic layers do not have excellent contact with thin film transistor (TFT) driving layer at boundary therebetween at a location corresponding to non-display area, it would be easy for water and oxygen to enter OLED devices through those portions of boundary having a shorter length, resulting in failure of OLED devices. In addition, once cracks are generated on a surface of TFT driving layer, thin film encapsulation layer disposed at a location corresponding to non-display area is prone to be damaged directly because there is no space for stress produced to be released, and water and oxygen thus enter OLED devices along cracks, resulting in failure of OLED devices.

Accordingly, in conventional OLED display apparatuses, the two inorganic layers do not have excellent contact with TFT driving layer at boundary therebetween at a location corresponding to non-display area, or cracks are generated on surface of TFT driving layer, making it easy for water and oxygen to enter OLED devices, oxidizing OLED devices, and reducing lifetime of OLED devices.

### SUMMARY OF DISCLOSURE

In conventional OLED display apparatuses, the two inorganic layers do not have excellent contact with thin film transistor (TFT) driving layer at boundary therebetween at a location corresponding to non-display area, or cracks are generated on surface of TFT driving layer, making it easy for water and oxygen to enter OLED devices, oxidizing OLED devices, and reducing lifetime of OLED devices.

The present disclosure provides an organic light emitting diode (OLED) display apparatus, which prevents OLED devices from being oxidized by water. The present disclosure solves the problems existing in conventional OLED display apparatuses, where the two inorganic layers do not have excellent contact with TFT driving layer at boundary therebetween at a location corresponding to non-display area, or cracks are generated on surface of TFT driving layer, making it easy for water and oxygen to enter OLED devices, oxidizing OLED devices, and reducing lifetime of OLED devices.

To solve the aforementioned problems, the present disclosure provides the following technical schemes.

The present disclosure provides an organic light emitting diode (OLED) display apparatus, comprising a flexible substrate, a thin film transistor (TFT) layer, an OLED illumination layer, and a thin film encapsulation layer. The flexible substrate includes a display area and a non-display area located at one side of the display area. The TFT layer includes at least two trenches at a location corresponding to the non-display area. The thin film encapsulation layer includes a first inorganic layer, an organic layer, and a second inorganic layer that are stacked from bottom to top, the first inorganic layer and the second inorganic layer extend from a location corresponding to the display area to a location corresponding to the non-display area, and the first inorganic layer and the second inorganic layer cover the trenches.

In the OLED display apparatus of the present disclosure, the TFT layer includes a buffer layer, a gate insulation layer, and an interlayer insulation layer that are stacked from bottom to top at a location corresponding to the non-display area.

In the OLED display apparatus of the present disclosure, the trenches are defined on a surface of the buffer layer.

In the OLED display apparatus of the present disclosure, the trenches are defined on a surface of the gate insulation layer.

In the OLED display apparatus of the present disclosure, a sidewall of each of the trenches is inclined at an angle less than or equal to 60 degrees that is counterclockwise from a horizontal plane.

In the OLED display apparatus of the present disclosure, each of the trenches has a width that is same to a distance between any two adjacent trenches.

In the OLED display apparatus of the present disclosure, the flexible substrate is made of polyimide.

In the OLED display apparatus of the present disclosure, the first inorganic layer and the second inorganic layer are made of silicon nitride, and the organic layer is made of polyacrylate.

In the OLED display apparatus of the present disclosure, the first inorganic layer has a thickness of 0.1-1.0 micrometers.

In the OLED display apparatus of the present disclosure, a thickness of the second inorganic layer is same to the thickness of the first inorganic layer, and a thickness of the organic layer is larger than a sum of the thickness of the first inorganic layer and the thickness of the second inorganic layer.

The present disclosure is characterized in that the OLED display apparatus includes at least two trenches in the TFT layer at a location corresponding to non-display area. Such structure prevents water and oxygen from entering OLED devices, further enhancing water/oxygen blocking ability of thin film encapsulation layer. Therefore, according to the present disclosure, the likelihood that OLED devices are oxidized is reduced, and stress that is produced due to expansion of cracks formed on substrate is released.

### BRIEF DESCRIPTION OF DRAWINGS

To explain in detail the technical schemes of the embodiments or existing techniques, drawings that are used to illustrate the embodiments or existing techniques are provided. The illustrated embodiments are just a part of those of the present disclosure. It is easy for any person having ordinary skill in the art to obtain other drawings without labor for inventiveness.

FIG. 1 is a schematic diagram showing a cross-sectional view of an OLED display apparatus of the present disclosure.

FIG. 1A is a cross-sectional view of an OLED display apparatus according to a first embodiment of the present disclosure, in which trenches are formed at a location corresponding to non-display area.

FIG. 1B is a cross-sectional view of an OLED display apparatus according to a second embodiment of the present disclosure, in which trenches are formed at a location corresponding to non-display area.

FIG. 2 is a schematic diagram showing a structure of a thin film encapsulation layer of an OLED display apparatus according to the present disclosure.

### DETAILED DESCRIPTION

The following embodiments refer to the accompanying drawings for exemplifying specific implementable embodiments of the present disclosure. Moreover, directional terms described by the present disclosure, such as upper, lower, front, back, left, right, inner, outer, side, etc., are only directions by referring to the accompanying drawings, and thus the used directional terms are used to describe and understand the present disclosure, but the present disclosure is not limited thereto. In the drawings, the same reference symbol represents the same or similar components.

The present disclosure solves the problems existing in conventional OLED display apparatuses, where the two inorganic layers do not have excellent contact with thin film transistor (TFT) driving layer at boundary therebetween at a location corresponding to non-display area, or cracks are generated on surface of TFT driving layer, making it easy for water and oxygen to enter OLED devices, oxidizing OLED devices, and reducing lifetime of OLED device.

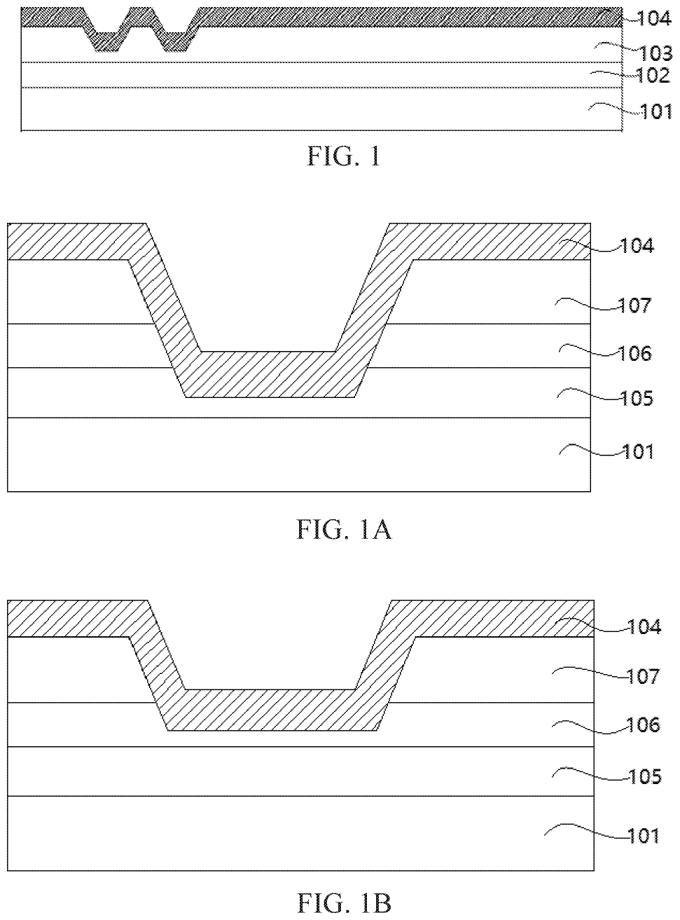

As shown in FIG. 1, the present disclosure provides an organic light emitting diode (OLED) display apparatus. The OLED display apparatus of the present disclosure includes a flexible substrate 101, a TFT layer 102, an OLED illumination layer 104, and a thin film encapsulation layer 104.

The OLED display apparatus is produced by carrying out following steps. First, a glass base plate is provided. A flexible substrate 101 is formed on surface of the glass base plate. The flexible substrate 101 is made of polyimide. The flexible substrate 101 is a plastic film having anti-abrasion property. The flexible substrate 101 includes a display area and a non-display area located at one side of the display area. A TFT layer 102 is deposited on the flexible substrate 101. The TFT layer 102 includes a buffer layer, a gate insulation layer, and an interlayer insulation layer that are stacked from bottom to top at a location corresponding to non-display area. The TFT layer 102 includes at least two trenches at a location corresponding to non-display area. An OLED illumination layer 103 is deposited on the TFT layer 102. A thin film encapsulation layer 104 is formed on the OLED illumination layer 103, and the thin film encapsulation layer 104 includes a first inorganic layer, an organic layer, and a second inorganic layer that are stacked from bottom to top. The first inorganic layer and the second inorganic layer extend from location corresponding to display area to location corresponding to non-display area, and the first inorganic layer and the second inorganic layer cover the trenches. Finally, the glass base plate is removed, thereby producing the OLED display apparatus. According to the present disclosure, a sidewall of each of the trenches is inclined at an angle less than or equal to 60 degrees that is counterclockwise from a horizontal plane. Each of the trenches has a width that is same to a distance between any two adjacent trenches. A depth of the trenches is larger than a sum of the thickness of the first inorganic layer and the thickness of the second inorganic layer.

FIG. 1A is a cross-sectional view of an OLED display apparatus according to a first embodiment of the present disclosure, in which trenches are formed at a location corresponding to non-display area. The TFT layer includes a buffer layer 105, a gate insulation layer 106, and an interlayer insulation layer 107 that are stacked from bottom to top at a location corresponding to non-display area. The buffer layer 105 is composed of silicon nitride layer(s) and silicon oxide layer(s) stacked on each other. The gate insulation layer 106 includes a first gate insulation layer and a second gate insulation layer, where the first gate insulation layer is made of silicon oxide, and the second gate insulation layer is made of silicon nitride. The interlayer insulation layer 107 is made of a same material as that used to form the buffer layer 105. The trenches are defined on a surface of the buffer layer 105.

FIG. 1B is a cross-sectional view of an OLED display apparatus according to a second embodiment of the present disclosure, in which trenches are formed at a location corresponding to non-display area. In the present embodiment, the trenches are defined on a surface of the gate insulation layer 106.

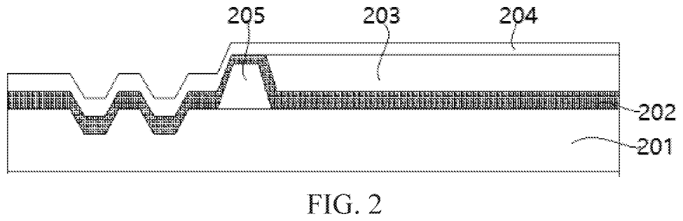

Please refer to FIG. 2, which is a schematic diagram showing a structure of a thin film encapsulation layer of an OLED display apparatus according to the present disclosure. A portion of the thin film encapsulation layer disposed at a location corresponding to display area includes a first inorganic layer 202, an organic layer 203, a second inorganic layer 204, and a barrier layer 205 formed on the OLED device 201. The OLED device 201 is formed on the flexible substrate (not shown). In addition, another portion of the thin film encapsulation layer disposed at a location corresponding to non-display area includes the first inorganic layer 202 and the second inorganic layer 204, and the first inorganic layer and the second inorganic layer completely cover the trenches.

The first inorganic layer 202 and the second inorganic layer 204 are made of silicon nitride, and the organic layer 203 is made of polyacrylate. The first inorganic layer 202 has a thickness of 0.1-1.0 micrometers. A thickness of the second inorganic layer 204 is same to the thickness of the first inorganic layer 202, and a thickness of the organic layer 203 is larger than a sum of the thickness of the first inorganic layer 202 and the thickness of the second inorganic layer 204. The organic layer 203 is formed at a location corresponding to display area. In addition, at boundary between the display area and the non-display area, the organic layer 203 is connected to the first inorganic layer 202 via sidewall of the organic layer 203.

According to the present disclosure, after OLED device is manufactured on the flexible substrate, at least two trenches are formed on OLED device 201. The OLED device 201 includes a TFT layer and an OLED illumination layer. The TFT layer includes a buffer layer, a gate insulation layer, and an interlayer insulation layer that are stacked from bottom to top at a location corresponding to non-display area. The trenches are defined on a surface of the buffer layer, or on a surface of the gate insulation layer

Preferably, a sidewall of each of the trenches is inclined at an angle less than or equal to 60 degrees that is counterclockwise from a horizontal plane. This ensures that, during formation of the thin film encapsulation layer, inorganic layers can be formed on sidewalls of trenches. Then, a thin film encapsulation process is performed to encapsulate the OLED device 201. According to the present disclosure, the thin film encapsulation process includes following steps.

The first inorganic layer 202 is deposited on the OLED device 201 first. There is a barrier layer 205 disposed at boundary between the display area and the non-display area. The first inorganic layer 202 is formed to extend from location corresponding to display area and go beyond the barrier layer 205, and cover the trenches. The barrier layer 205 is an organic layer. The barrier layer 205 is formed on the OLED device 201, and the first inorganic layer 202 tightly surrounds the barrier layer 205.

Preferably, the first inorganic layer 202 is made of an inorganic material, such as silicon nitride or aluminum oxide. The first inorganic layer 202 is a hydrophilic film. The first inorganic layer 202 has a thickness of 0.1-1.0 micrometers, such as 0.5 micrometers. The first inorganic layer 202 is formed preferably using plasma enhanced chemical vapor deposition (PECVD) or atomic layer deposition (ALM). The PECVD is a technique which uses microwave or radio frequency to dissociate gases used to form a thin film. Since plasma is generated, and plasma is highly reactive, thin film could be formed on surface of the OLED device 201. ALM is a technique where thin film is formed by sequentially depositing a single atom layer one at a time on substrate surface.

After the first inorganic layer 202 is formed on the OLED device 201, the organic layer 203 is formed on the first inorganic layer 202. The sidewall of the organic layer 203 is stopped by the barrier layer 205 at boundary between the display area and the non-display area. That is, the barrier layer 205 limits flowing region of the organic layer 203.

The organic layer 203 is formed from an organic polymer, preferably from polyacrylate. A thickness of the organic layer 203 is greater than a thickness of the first inorganic layer 202, and the organic layer 203 preferably has a thickness ranging from 0.3-3.0 micrometers, such as 2 micrometers. The organic layer 203 is formed on the first inorganic layer 202 using ink-jet printing (IJP). The ink used in IJP includes components of acrylate organic compound and photopolymerization initiator, where acrylate organic compound has a weight percentage of 0.1-10 wt % in the ink.

After the organic layer 203 is formed on the first inorganic layer 202, the second inorganic layer 204 is formed on the OLED device 201. The second inorganic layer 204 is formed to extend from location corresponding to display area and go beyond the barrier layer 205, and cover the trenches.

The second inorganic layer 204 is made of an inorganic material, such as aluminum oxide, silicon oxide, or silicon nitride. A thickness of the second inorganic layer 204 is same to the thickness of the first inorganic layer 202, and the second inorganic layer 204 preferably has a thickness of 0.1-1.0 micrometers, such as 0.5 micrometers. The second inorganic layer 204 is formed using plasma enhanced chemical vapor deposition (PECVD) or atomic layer deposition (ALM). In the display area, the second inorganic layer 204 completely covers the organic layer 203, and the second inorganic layer 204 directly connects to the first inorganic layer 202 at outer region of the display area, therefore the organic layer 203 is sealed within the two inorganic layers, thus blocking water and oxygen from entering the organic layer 203 through outer region. In the non-display area, the second inorganic layer 204 completely covers the first inorganic layer 202, and completely covers the trenches. The trenches can prevent water and oxygen from entering OLED devices. Moreover, the trenches can release stress that is produced due to expansion of cracks formed on substrate surface. In other words, formation of trenches solves the problems, where the substrate does not have space to release stress, and water and oxygen enter the OLED devices along cracks, resulting in failure of OLED devices.

The present disclosure is characterized in that the OLED display apparatus includes at least two trenches in the TFT layer at a location corresponding to non-display area. Such structure prevents water and oxygen from entering OLED devices, further enhancing water/oxygen blocking ability of thin film encapsulation layer. Therefore, according to the present disclosure, the likelihood that OLED devices are oxidized is reduced, and stress that is produced due to expansion of cracks formed on substrate is released.

While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

What is claimed is:

1. An organic light emitting diode (OLED) display apparatus, comprising:
a flexible substrate, wherein the flexible substrate includes a display area and a non-display area located at one side of the display area;
a thin film transistor (TFT) layer and an OLED illumination layer disposed on the flexible substrate, wherein the TFT layer includes at least two trenches at a location corresponding to the non-display area;
a thin film encapsulation layer, wherein the thin film encapsulation layer includes a first inorganic layer, an organic layer, and a second inorganic layer that are stacked from bottom to top, the first inorganic layer and the second inorganic layer extend from a location corresponding to the display area to a location corresponding to the non-display area, and the first inorganic layer and the second inorganic layer cover the trenches.

2. The OLED display apparatus according to claim 1, wherein the TFT layer includes a buffer layer, a gate insulation layer, and an interlayer insulation layer that are stacked from bottom to top at a location corresponding to the non-display area.

3. The OLED display apparatus according to claim 2, wherein the trenches are defined on a surface of the buffer layer.

4. The OLED display apparatus according to claim 2, wherein the trenches are defined on a surface of the gate insulation layer.

5. The OLED display apparatus according to claim 1, wherein a sidewall of each of the trenches is inclined at an angle less than or equal to 60 degrees that is counterclockwise from a horizontal plane.

6. The OLED display apparatus according to claim 5, wherein each of the trenches has a width that is same to a distance between any two adjacent trenches.

7. The OLED display apparatus according to claim 1, wherein the flexible substrate is made of polyimide.

8. The OLED display apparatus according to claim 1, wherein the first inorganic layer and the second inorganic layer are made of silicon nitride, and the organic layer is made of polyacrylate.

9. The OLED display apparatus according to claim 8, wherein the first inorganic layer has a thickness of 0.1-1.0 micrometers.

10. The OLED display apparatus according to claim 9, wherein a thickness of the second inorganic layer is same to the thickness of the first inorganic layer, and a thickness of the organic layer is larger than a sum of the thickness of the first inorganic layer and the thickness of the second inorganic layer.
